(19) United States
(12) Patent Application Publication
(10) Pub. No.: US 2022/0172928 A1
(43) Pub. Date: Jun. 2, 2022

(54) PLASMA PROCESSING APPARATUS AND METHOD FOR FABRICATING SEMICONDUCTOR DEVICE USING THE SAME

(71) Applicant: SEMES Co., Ltd., Chungcheongnam-do (KR)

(72) Inventors: Soo Ryun Ro, Gyeonggi-do (KR); Jeong Seok Kang, Gyeonggi-do (KR); Young Hwan Yang, Gyeonggi-do (KR); Hak Jun Lee, Chungcheongnam-do (KR)

(21) Appl. No.: 17/533,507

(22) Filed: Nov. 23, 2021

(30) Foreign Application Priority Data
Nov. 30, 2020 (KR) 10-2020-0163985

(51) Int. Cl. H01J 37/32; G01J 3/02; H01L 21/67

(52) U.S. Cl. CPC H01J 37/32449; H01L 21/67069; H01L 21/67253; G01J 3/0208

(57) ABSTRACT

A plasma processing apparatus is provided. A plasma processing apparatus includes a chamber, in which a plasma process is performed, a chuck disposed inside the chamber and provided with a wafer, a gas feeder disposed on the chuck and for providing process gas to the inside of the chamber, an OES port extending in a vertical direction along a sidewall of the chamber, and for receiving each of a first light emitted from plasma at a first position and a second light emitted from plasma at a second position closer to the gas feeder than the first position, an OES sensor for sensing the first light to measure first plasma data, and sensing the second light to measure second plasma data, and a control unit for controlling the plasma process using the first and second plasma data.

### CROSS REFERENCE TO RELATED APPLICATION

This application claims the benefit of Korean Patent Application No. 10-2020-0163985, filed on Nov. 30, 2020, in the Korean Intellectual Property Office, the disclosure of which is incorporated herein by reference in its entirety.

### FIELD OF THE INVENTION

The present disclosure relates to a plasma processing apparatus and a method for manufacturing a semiconductor device using the plasma processing apparatus.

### BACKGROUND OF THE INVENTION

In general, a semiconductor device or a flat panel display device is formed by selectively and repeatedly performing processes such as diffusion, deposition, photography, etching, and ion implantation on a substrate. Among these manufacturing processes, etching, diffusion, and deposition processes are performed so that a reaction occurs on a substrate in the process chamber by introducing a process gas in a predetermined atmosphere into the sealed process chamber.

When a process using plasma is performed in a process chamber, a plasma state is formed differently depending on a position in the process chamber, and thus, it is difficult to predict the plasma process. Therefore, in order to solve this problem, research for monitoring the plasma state in the process chamber is in progress.

### SUMMARY OF THE INVENTION

The aspect of the present disclosure is a plasma processing apparatus capable of receiving light generated from plasma at various positions spaced apart from each other in a vertical direction inside a chamber by disposing an OES lens to correspond to various positions in a vertical direction, and a method for manufacturing a semiconductor device using the plasma processing apparatus. Due to this, the plasma processing apparatus and the method for manufacturing a semiconductor device using the plasma processing apparatus can improve the reliability of the plasma process by effectively monitoring the plasma state generated inside the chamber.

The aspects of the present disclosure are not limited to the problems mentioned above, and other aspects not mentioned will be clearly understood by those skilled in the art from the following description.

One aspect of the plasma processing apparatus of the present disclosure for achieving the above object comprise a chamber, in which a plasma process is performed, a chuck disposed inside the chamber and provided with a wafer, a gas feeder disposed on the chuck and for providing a process gas to an inside of the chamber, an OES port extending in a vertical direction along a sidewall of the chamber, and for receiving each of a first light emitted from plasma at a first position and a second light emitted from plasma at a second position closer to the gas feeder than the first position, an OES sensor for sensing the first light to measure first plasma data, and sensing the second light to measure second plasma data, and a control unit for controlling the plasma process using the first and second plasma data.

Another aspect of the plasma processing apparatus of the present disclosure for achieving the above object comprise a chamber, in which a plasma process is performed, a flange extending in a vertical direction along a sidewall of the chamber and having a width in the vertical direction greater than a width in a horizontal direction, an OES lens surrounded by the flange, and for receiving each of a first light emitted from plasma at a first position and a second light emitted from plasma at a second position spaced apart from the first position in the vertical direction, an OES sensor for sensing the first light to measure first plasma data, and sensing the second light to measure second plasma data, an optical cable connecting between the OES lens and the OES sensor, and a control unit for controlling the plasma process using the first and second plasma data.

One aspect of the method of manufacturing a semiconductor device of the present disclosure for achieving the above object comprises providing a wafer inside a chamber, in which a plasma process is performed, generating plasma inside the chamber, providing each of a first light emitted from plasma at a first position and a second light emitted from plasma at a second position spaced apart from the first position in a vertical direction to an OES sensor through an OES port formed in a sidewall of the chamber, measuring first plasma data by sensing the first light, and measuring second plasma data by sensing the second light, and controlling the plasma process using the first and second plasma data, wherein, in the OES port, a width in the vertical direction is greater than a width in a horizontal direction.

The details of other embodiments are included in the detailed description and drawings.

### BRIEF DESCRIPTION OF THE DRAWINGS

These and/or other aspects will become apparent and more readily appreciated from the following description of the embodiments, taken in conjunction with the accompanying drawings in which:

FIG. 1 is a view for describing a plasma processing apparatus according to some embodiments of the present disclosure;

FIG. 2 is a view for describing an OES port of a plasma processing apparatus according to some embodiments of the present disclosure;

FIG. 3 is a flowchart illustrating a method of manufacturing a semiconductor device according to some embodiments of the present disclosure;

FIG. 4 is a view for describing a plasma processing apparatus according to some other embodiments of the present disclosure;

FIG. 5 is a diagram for describing an OES port of a plasma processing apparatus according to another exemplary embodiment of the present disclosure;

FIG. 6 is a flowchart illustrating a method of manufacturing a semiconductor device according to another exemplary embodiment of the present disclosure;

FIG. 7 is a flowchart illustrating a method of manufacturing a semiconductor device according to still another exemplary embodiment of the present disclosure;

FIG. 8 is a view for describing a plasma processing apparatus according to another exemplary embodiment of the present disclosure;

FIG. 9 is a view for describing an OES port of a plasma processing apparatus according to another exemplary embodiment of the present disclosure;

FIGS. 10 and 11 are diagrams for describing an operation of an OES port of a plasma processing apparatus according to another exemplary embodiment of the present disclosure; and

FIG. 12 is a flowchart illustrating a method of manufacturing a semiconductor device according to still another exemplary embodiment of the present disclosure.

### DETAILED DESCRIPTION OF THE INVENTION

Hereinafter, preferred embodiments of the present invention will be described in detail with reference to the accompanying drawings. Advantages and features of the present invention and methods of achieving them will become apparent with reference to the embodiments described below in detail in conjunction with the accompanying drawings. However, the present invention is not limited to the embodiments described below, but may be implemented in various different forms, and these embodiments are provided only for making the description of the present invention complete and fully informing those skilled in the art to which the present invention pertains on the scope of the invention, and the present invention is only defined by the scope of the claims. Like reference numerals refer to like elements throughout.

Spatially relative terms “below,” “beneath,” “lower,” “above,” and “upper” can be used to easily describe a correlation between an element or components and other elements or components. The spatially relative terms should be understood as terms including different orientations of the device during use or operation in addition to the orientation shown in the drawings. For example, when an element shown in the figures is turned over, an element described as “below” or “beneath” another element may be placed “above” the other element. Accordingly, the exemplary term “below” may include both directions below and above. The device may also be oriented in other orientations, and thus spatially relative terms may be interpreted according to orientation.

Although first, second, etc. are used to describe various elements, components, and/or sections, it should be understood that these elements, components, and/or sections are not limited by these terms. These terms are only used to distinguish one element, component, or section from another element, component, or section. Accordingly, the first element, the first component, or the first section mentioned below may be the second element, the second component, or the second section within the technical spirit of the present invention.

The terminology used herein is for the purpose of describing the embodiments and is not intended to limit the present invention. In this specification, the singular also includes the plural unless specifically stated otherwise in the phrase. As used herein, “comprises” and/or “comprising” refers to the presence of one or more other components, steps, operations and/or elements mentioned. or addition is not excluded.

Unless otherwise defined, all terms (including technical and scientific terms) used herein may be used with the meaning commonly understood by those of ordinary skill in the art to which the present invention belongs. In addition, terms defined in a commonly used dictionary are not to be interpreted ideally or excessively unless clearly specifically defined.

Hereinafter, embodiments of the present invention will be described in detail with reference to the accompanying drawings. In the description with reference to the accompanying drawings, the same or corresponding components are assigned the same reference numerals regardless of reference numerals in the drawings, and overlapping descriptions thereof will be omitted.

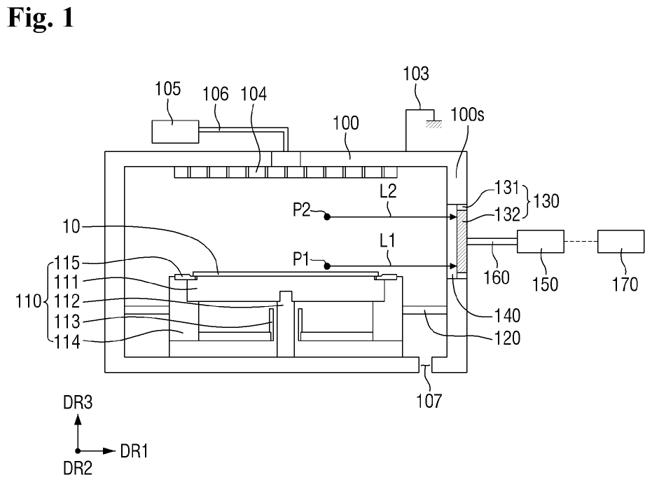

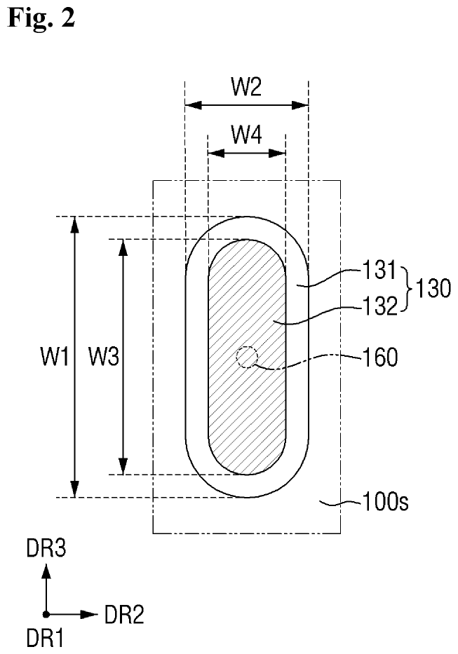

Hereinafter, a plasma processing apparatus according to some embodiments of the present disclosure will be described with reference to FIGS. 1 and 2.

FIG. 1 is a view for describing a plasma processing apparatus according to some embodiments of the present disclosure. FIG. 2 is a view for describing an OES port of a plasma processing apparatus according to some embodiments of the present disclosure.

Referring to FIGS. 1 and 2, the plasma processing apparatus according to some embodiments of the present disclosure includes a chamber 100, a ground line 103, a gas feeder 104, a gas source 105, a gas supply line 106, an exhaust port 107, a chuck 110, a baffle unit 120, an OES (Optical Emission Spectroscopy) port 130, a view port 140, an OES sensor 150, an optical cable 160 and a control unit 170.

The chamber 100 may serve as a housing comprising other components therein. The chamber 100 may be a kind of isolated space, in which a plasma process is performed on the wafer 10. As the chamber 100 is isolated from the outside, the process conditions of the plasma process may be adjusted. For example, process conditions such as temperature or pressure inside the chamber 100 may be adjusted differently from those of the outside.

The gas feeder 104 may be disposed on the ceiling of the chamber 100. The gas feeder 104 may be located on the chuck 110. The gas feeder 104 may be grounded via a ground line 103. The gas feeder 104 may provide gas toward the upper surface of the wafer 10 seated on the chuck 110.

The gas feeder 104 may provide a process gas used for plasma generation to the inside of the chamber 100 using a plurality of nozzles. In some embodiments, the gas feeder 104 may include an upper electrode for the plasma process. In some other embodiments, the gas feeder 104 may directly serve as an upper electrode.

The plasma process may include performing dry etching on the upper surface of the wafer 10 using a gas plasma used for plasma. That is, the gas feeder 104 may provide the gas used for the plasma process to the inside of the chamber 100.

The gas supply line 106 may be connected to the gas feeder 104. The gas supply line 106 may be connected to the ceiling of the chamber 100. The gas supply line 106 may be connected to the gas source 105 outside the chamber 100. The gas supply line 106 may provide gas used for plasma provided from the gas source 105 into the chamber 100. Although the gas supply line 106 is shown as being disposed on the ceiling of the chamber 100 in FIG. 1, the position of the gas supply line 106 is not limited. The position of the gas supply line 106 may vary depending on the structure and position of the chamber 100 and the position of the gas source 105.

The gas source 105 may store a gas used for plasma generation and provide the gas to the inside of the chamber 100 during a plasma process. Although it is illustrated in FIG. 1 that the gas source 105 provides gas through the gas supply line 106 from the outside of the chamber 100, the technical spirit of the present disclosure is not limited thereto. In some other embodiments, the gas source 105 may be attached directly to the chamber 100.

The chuck 110 may be disposed inside the chamber 100. The wafer 10 may be provided on the upper surface of the chuck 110. The chuck 110 may be, for example, an electrostatic chuck. That is, the chuck 110 may chuck the wafer 10 by generating an electrostatic attraction using the RF signal provided to the chuck 110.

The chuck 110 may include a lower electrode 111, an RF rod 112, a ground electrode 113, an insulating plate 114, and a focus ring 115.

The RF rod 112 may be disposed on the bottom surface of the chamber 100. The RF rod 112 may extend in the vertical direction DR3. The RF rod 112 may provide an RF signal to the lower electrode.

The lower electrode 111 may be disposed on the RF rod 112. The lower electrode 111 may form an upper portion of the chuck 110. The wafer 10 may be provided on the upper surface of the lower electrode 111. The lower electrode 111 may chuck the wafer 10 using an RF signal provided from the RF rod 112.

The ground electrode 113 may surround a sidewall of the RF rod 112. The ground electrode 113 may be spaced apart from the sidewall of the RF rod 112. Also, the ground electrode 113 may be spaced apart from the lower electrode 111.

The insulating plate 114 may surround a sidewall of the lower electrode 111. The insulating plate 114 may be in contact with the lower electrode 111. The insulating plate 114 may form an outer wall of the chuck 110. The insulating plate 114 may include an insulating material, for example, ceramic.

The focus ring 115 may be disposed on an edge of an upper surface of the lower electrode 111 and at least a portion of an upper surface of the insulating plate 114. The focus ring 115 may surround a sidewall of a part of an upper portion of the lower electrode 111. The focus ring 115 may have a ring shape on a plane defined by the first horizontal direction DR1 and the second horizontal direction DR2 perpendicular to the first horizontal direction DR1. The focus ring 115 may include an insulating material.

The baffle unit 120 may be disposed between the insulating plate 114 and the sidewall 100s of the chamber 100. The baffle unit 120 may contact the sidewall 100s of the chamber 100 and the sidewall of the insulating plate 114, respectively. However, the technical spirit of the present disclosure is not limited thereto.

The baffle unit 120 may have a ring shape. The baffle unit 120 may include a plurality of baffle holes penetrating through the baffle unit 120 in the vertical direction DR3. Each of the plurality of baffle holes may be spaced apart from each other. The process gas present inside the chamber 100 may be exhausted through the baffle hole formed in the baffle unit 120. The process gas passing through the baffle unit 120 may be exhausted to the outside of the chamber 100 through a exhaust port 107 formed on the bottom surface of the chamber 100.

The OES port 130 may be disposed on the sidewall 100s of the chamber 100. The OES port 130 may include a flange 131 and an OES lens 132. The flange 131 may be connected to the inner wall of the chamber 100. The OES port 130 may be connected to the inner wall of the chamber through the flange 131. The OES lens 132 may be surrounded by the flange 131.

The OES port 130 may extend in the vertical direction DR3 along the sidewall 100s of the chamber 100. The width W1 of the OES port 130 in the vertical direction DR3 may be greater than the width W2 of the OES port 130 in the second horizontal direction DR2. That is, the width W1 of the flange 131 in the vertical direction DR3 may be greater than the width W2 of the flange 131 in the second horizontal direction DR2.

The OES lens 132 may extend in the vertical direction DR3 along the sidewall 100s of the chamber 100. The width W3 of the OES lens 132 in the vertical direction DR3 may be greater than the width W4 of the OES lens 132 in the second horizontal direction DR2.

The OES port 130 may receive light emitted from the plasma generated inside the chamber 100. Specifically, the OES lens 132 disposed in the OES port 130 may receive light emitted from the plasma generated inside the chamber 100.

For example, the OES lens 132 may receive the first light L1 emitted from the plasma at the first position P1 adjacent to the wafer 10. In addition, the OES lens 132 may receive the second light L2 emitted from the plasma at the second position P2 adjacent to the gas feeder 104. The second position P2 may be closer to the gas feeder 104 than the first position P1. The second position P2 may be spaced apart from the first position P1 in the vertical direction DR3.

The view port 140 may be disposed between the inside of the chamber 100 and the OES port 130. The view port 140 may allow light generated from plasma inside the chamber 100 to pass therethrough. The view port 140 may protect the OES lens 132 while a plasma process is performed in the chamber 100. However, the technical spirit of the present disclosure is not limited thereto. In some other embodiments, the view port 140 may be omitted.

The optical cable 160 may be connected to the OES port 130. Specifically, the optical cable 160 may be connected to the OES lens 132 disposed in the OES port 130.

The OES sensor 150 may be connected to the optical cable 160. The OES sensor 150 may be connected to the OES port 130 through an optical cable 160. Although the OES sensor 150 is illustrated as being disposed outside the chamber 100 in FIG. 1, the technical spirit of the present disclosure is not limited thereto. In some other embodiments, the OES sensor 150 may be disposed inside the chamber 100.

The first light L1 generated from the plasma at the first position P1 and the second light L2 generated from the plasma at the second position P2 may be respectively provided to the OES sensor 150 passing through the OES lens 132 and the optical cable 160.

The OES sensor 150 may measure the first plasma data by sensing the plasma state at the first position P1 using the first light L1. Also, the OES sensor 150 may measure the second plasma data by sensing the plasma state at the second position P2 using the second light L2.

The control unit 170 may control the plasma process inside the chamber 100 using the first plasma data and the second plasma data measured by the OES sensor 150.

Hereinafter, a method of manufacturing a semiconductor device according to some exemplary embodiments of the present disclosure will be described with reference to FIGS. 1 to 3.

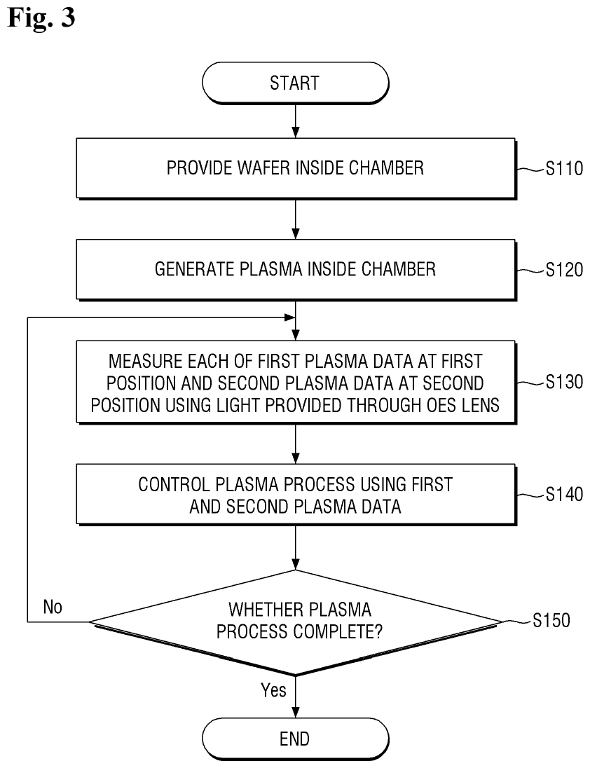

FIG. 3 is a flowchart illustrating a method of manufacturing a semiconductor device according to some embodiments of the present disclosure.

Referring to FIGS. 1 to 3, a wafer 10 may be provided inside the chamber 100 (S110). The wafer 10 may be provided on the chuck 110 disposed inside the chamber 100. Subsequently, plasma may be generated inside the chamber 100 using the process gas provided from the gas feeder 104 (S120).

Then, the OES lens 132 may receive a first light L1 emitted from the plasma at a first position P1 adjacent to the wafer 10 and a second light L2 emitted from a plasma at a second position P2 adjacent to the gas feeder 104. Each of the first light L1 and the second light L2 may be provided to the OES sensor 150 through the optical cable 160.

The OES sensor 150 may measure the first plasma data by sensing the plasma state at the first position P1 using the first light L1. Also, the OES sensor 150 may measure the second plasma data by sensing the plasma state at the second position P2 using the second light L2 (S130).

The first plasma data and the second plasma data may be measured simultaneously. That is, while the OES sensor 150 measures the first plasma data by sensing the plasma state at the first position P1 using the first light L1, the OES sensor 150 may measure the second plasma data by sensing the plasma state at the second position P2 using the second light L2. However, the technical spirit of the present disclosure is not limited thereto.

In some other embodiments, the first plasma data and the second plasma data may be sequentially measured. That is, the OES sensor 150 may measure the first plasma data by sensing the plasma state at the first position P1 using the first light L1, and then measure the second plasma data by sensing the plasma state at the position P2 using the second light L2. In this case, the measurement of the first plasma data and the measurement of the second plasma data may be repeated.

Subsequently, the control unit 170 may control the plasma process inside the chamber 100 using the first plasma data and the second plasma data measured by the OES sensor 150 (S140).

Subsequently, when the plasma process inside the chamber 100 is not completed, the measurement of the first and second plasma data using the OES sensor 150 and the control of the plasma process using the control unit 170 may be repeated again (S150).

When the plasma process inside the chamber 100 is completed, the measurement of the first and second plasma data using the OES sensor 150 and the control of the plasma process using the control unit 170 may be stopped.

In the plasma processing apparatus and the method of manufacturing a semiconductor device using the plasma processing apparatus according to some embodiments of the present disclosure, light generated from plasma at various positions spaced apart from each other in the vertical direction DR3 inside the chamber 100 may be received by disposing the OES lens 132 to extend in the vertical direction DR3. Due to this, the plasma processing apparatus and the method of manufacturing a semiconductor device using the plasma processing apparatus according to some embodiments of the present disclosure can effectively monitor the plasma state generated inside the chamber 100 to improve the reliability of the plasma process.

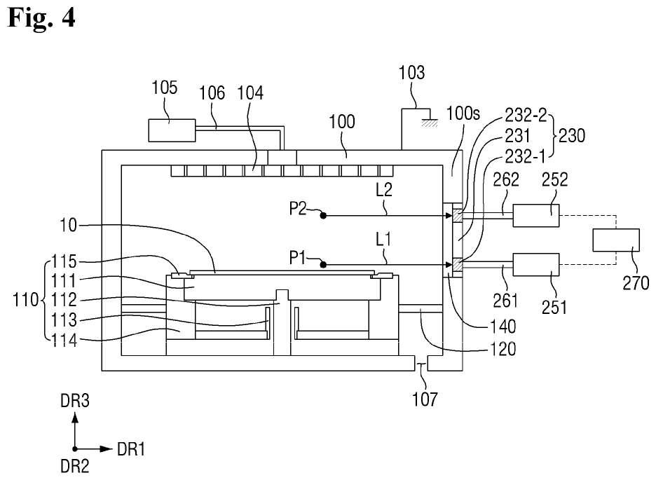

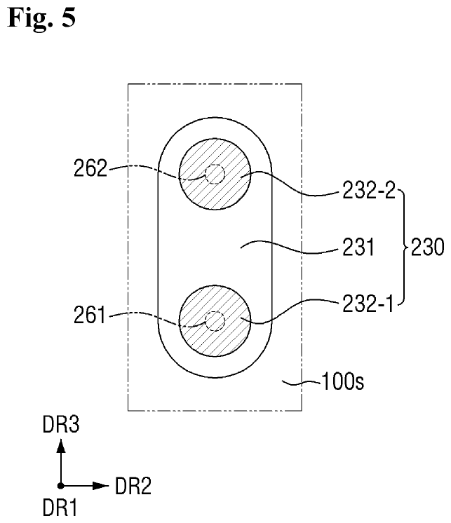

Hereinafter, a plasma processing apparatus according to some other exemplary embodiments of the present disclosure will be described with reference to FIGS. 4 and 5. Differences from the plasma processing apparatus shown in FIGS. 1 and 2 will be mainly described.

FIG. 4 is a view for describing a plasma processing apparatus according to some other embodiments of the present disclosure. FIG. 5 is a diagram for describing an OES port of a plasma processing apparatus according to another exemplary embodiment of the present disclosure.

Referring to FIGS. 4 and 5, in the plasma processing apparatus according to some embodiments of the present disclosure, the OES port 230 may include a flange 231, a first OES lens 232-1, and a second OES lens 232-2.

In FIGS. 4 and 5, the OES port 230 is shown to include two OES lenses 232-1 and 232-2 spaced apart from each other in the vertical direction DR3, but the technical spirit of the present disclosure is not limited thereto. In some other embodiments, OES port 230 may include three or more OES lenses. Hereinafter, it will be exemplarily described that the OES port 230 includes two OES lenses 232-1 and 232-2 spaced apart from each other in the vertical direction DR3.

The second OES lens 232-2 may be spaced apart from the first OES lens 232-1 in the vertical direction DR3. Each of the first OES lens 232-1 and the second OES lens 232-2 may be surrounded by the flange 231.

The first OES lens 232-1 may receive the first light L1 emitted from the plasma at the first position P1. The second OES lens 232-2 may receive the second light L2 emitted from the plasma at the second position P2.

The first OES lens 232-1 may be connected to the first OES sensor 251 through the first optical cable 261. The second OES lens 232-2 may be connected to the second OES sensor 252 through the second optical cable 262.

The first OES sensor 251 may measure the first plasma data by sensing the plasma state at the first position P1 using the first light L1 provided through the first OES lens 232-1. The second OES sensor 252 may measure the second plasma data by sensing the plasma state at the second position P2 using the second light L2 provided through the second OES lens 232-2.

The control unit 270 controls the plasma process inside the chamber 100 using the first plasma data measured by the first OES sensor 251 and the second plasma data measured by the second OES sensor 252.

Hereinafter, a method of manufacturing a semiconductor device according to some other exemplary embodiments of the present disclosure will be described with reference to FIGS. 4 to 6. Differences from the method of manufacturing the semiconductor device shown in FIG. 3 will be mainly described.

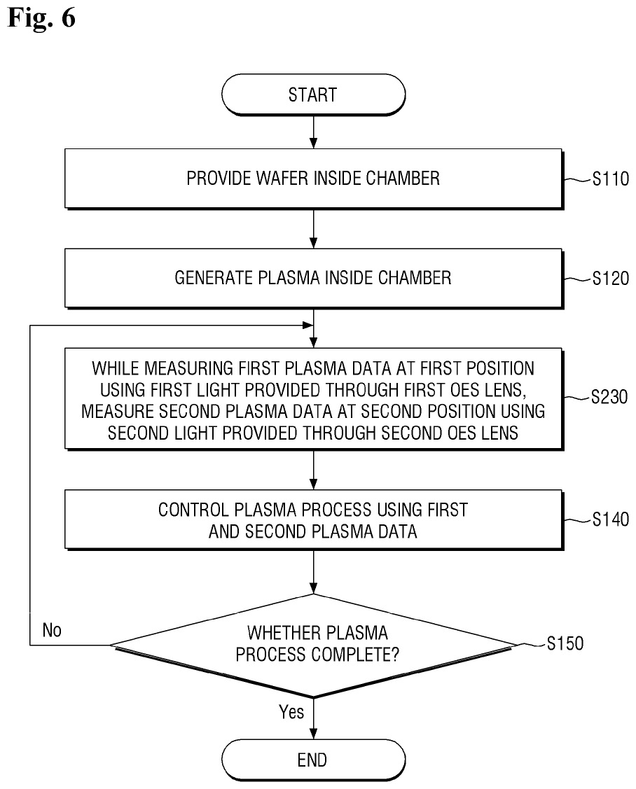

FIG. 6 is a flowchart illustrating a method of manufacturing a semiconductor device according to another exemplary embodiment of the present disclosure.

Referring to FIGS. 4 to 6, after plasma is generated in the chamber 100 using the process gas provided from the gas feeder 104 (S120), the measurement of the first plasma data using the first OES sensor 251 and the measurement of the second plasma data using the second OES sensor 252 may be simultaneously performed.

That is, while the first OES sensor 251 measures the first plasma data by sensing the plasma state at the first position P1 using the first light L1, the second OES sensor 252 may measure the second plasma data by sensing the plasma state at the second position P2 using the second light L2 (S230).

Subsequently, the control unit 270 may control the plasma process inside the chamber 100 using the first plasma data measured by the first OES sensor 251 and the second plasma data measured by the second OES sensor 252 (S140).

Subsequently, when the plasma process inside the chamber 100 is not completed, the measurement of the first plasma data using the first OES sensor 251, the measurement of the second plasma data using the second OES sensor 252, and the control of the plasma process using the control unit 270 may be repeated again (S150).

When the plasma process inside the chamber 100 is completed, the measurement of the first plasma data using the first OES sensor 251, the measurement of the second plasma data using the second OES sensor 252, and the control of the plasma process using the control unit 270 may be stopped.

Hereinafter, a method of manufacturing a semiconductor device according to some other exemplary embodiments of the present disclosure will be described with reference to FIGS. 4, 5 and 7. Differences from the method of manufacturing the semiconductor device shown in FIG. 3 will be mainly described.

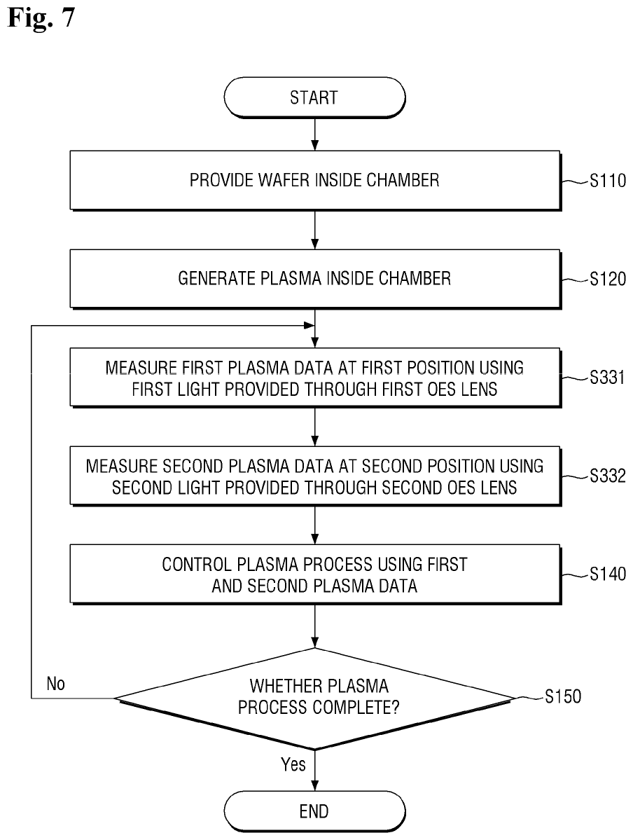

FIG. 7 is a flowchart illustrating a method of manufacturing a semiconductor device according to still another exemplary embodiment of the present disclosure.

Referring to FIGS. 4, 5, and 7, after plasma is generated inside the chamber 100 using the process gas provided from the gas feeder 104 (S120), the measurement of the first plasma data using the first OES sensor 251 and the measurement of the second plasma data using the second OES sensor 252 may be sequentially performed.

That is, after the first OES sensor 251 measures the first plasma data by sensing the plasma state at the first position P1 using the first light L1 (S331), the second OES sensor 252 may measure the second plasma data by sensing the plasma state at the second position P2 using the second light L2 (S332).

Subsequently, the control unit 270 may control the plasma process inside the chamber 100 using the first plasma data measured by the first OES sensor 251 and the second plasma data measured by the second OES sensor 252 (S140).

Subsequently, when the plasma process inside the chamber 100 is not completed, the measurement of the first plasma data using the first OES sensor 251, the measurement of the second plasma data using the second OES sensor 252, and the control of the plasma process using the control unit 270 may be repeated again (S150).

When the plasma process inside the chamber 100 is completed, the measurement of the first plasma data using the first OES sensor 251, the measurement of the second plasma data using the second OES sensor 252, and control of the plasma process using the control unit 270 may be stopped.

A plasma processing apparatus and a method of manufacturing a semiconductor device using the plasma processing apparatus according to some embodiments of the present disclosure may receive light generated from plasma at various positions spaced apart from each other in the vertical direction DR3 inside the chamber 100 by disposing a plurality of OES lenses 232-1 and 232-2 to be spaced apart from each other in the vertical direction DR3. Due to this, the plasma processing apparatus and the method of manufacturing a semiconductor device using the plasma processing apparatus according to some embodiments of the present disclosure can effectively monitor the plasma state generated inside the chamber 100 to improve the reliability of the plasma process.

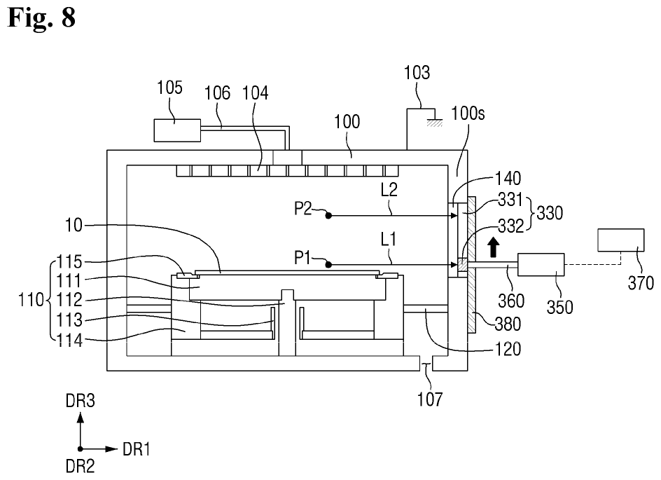

Hereinafter, a plasma processing apparatus according to another exemplary embodiment of the present disclosure will be described with reference to FIGS. 8 to 11. Differences from the plasma processing apparatus shown in FIGS. 1 and 2 will be mainly described.

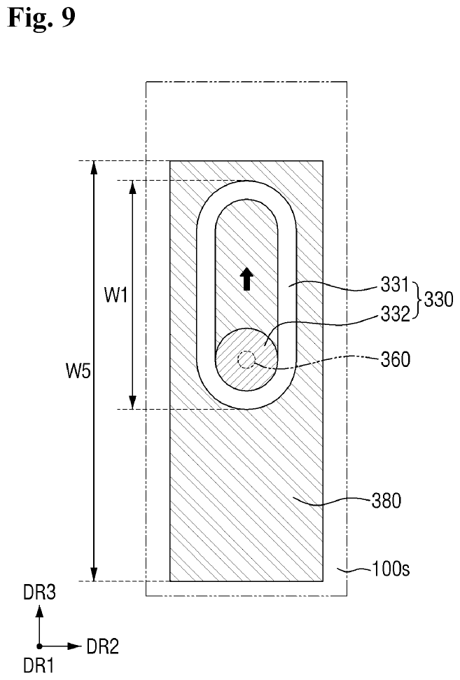

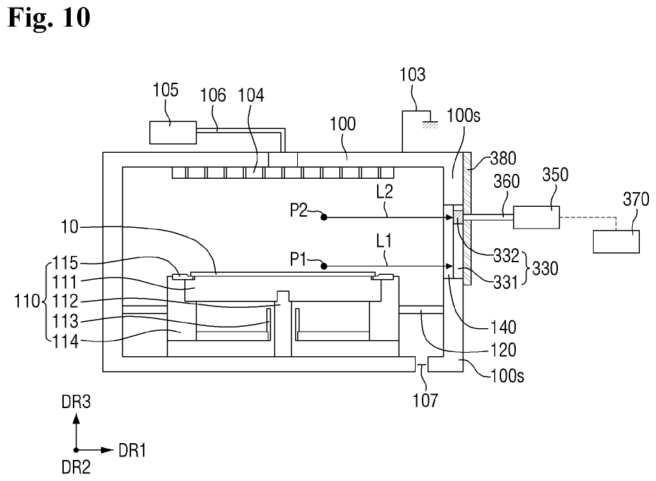

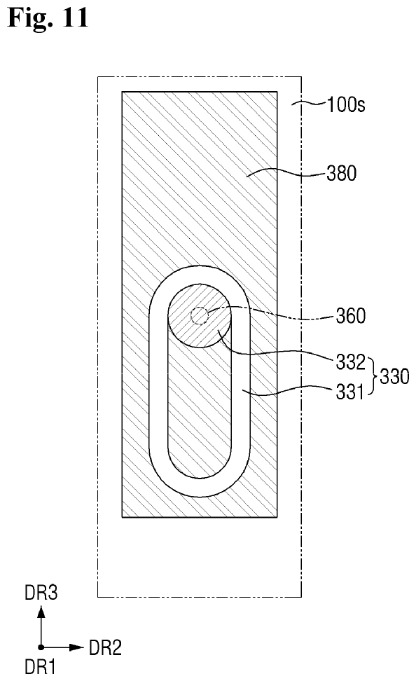

FIG. 8 is a view for describing a plasma processing apparatus according to another exemplary embodiment of the present disclosure. FIG. 9 is a view for describing an OES port of a plasma processing apparatus according to another exemplary embodiment of the present disclosure. FIGS. 10 and 11 are diagrams for describing an operation of an OES port of a plasma processing apparatus according to another exemplary embodiment of the present disclosure.

Referring to FIGS. 8 to 11, in the plasma processing apparatus according to another exemplary embodiment of the present invention, the OES lens 332 may move in the vertical direction DR3.

The OES port 330 may include a flange 331 and an OES lens 332 surrounded by the flange 331. The OES lens 332 may move in the vertical direction DR3 along the flange 331. While the OES lens 332 moves in the vertical direction DR3, the flange 331 may be fixed while being connected to the chamber 100.

The OES lens 332 may be connected to the OES sensor 350 via an optical cable 360. The optical cable 360 may move in the vertical direction DR3 together with the OES lens 332 while being connected to the OES lens 332. In FIGS. 8 and 10, the OES sensor 350 is shown to move in the vertical direction DR3 together with the OES lens 332 in a state connected to the optical cable 360, but the technical spirit of the present disclosure is not limited thereto. In some other embodiments, the OES sensor 350 may be fixed regardless of movement of the OES lens 332 and the optical cable 360.

The cap 380 may be installed on the outer wall of the chamber 100. The cap 380 may be connected to each of the OES lens 332 and the optical cable 360. The cap 380 may surround at least a portion of the optical cable 360.

The cap 380 may move in the vertical direction DR3 together with the OES lens 332 and the optical cable 360, respectively. The cap 380 may move in the vertical direction DR3 along the outer wall of the chamber 100.

The cap 380 may seal the space between the flange 331 and the OES lens 332. Accordingly, even when the OES lens 332 moves in the vertical direction DR3, the chamber 100 may be sealed using the cap 380. The cap 380 may have, for example, a flat plate shape, but the technical spirit of the present disclosure is not limited thereto.

The width W5 of the cap 380 in the vertical direction DR3 may be greater than the width W1 of the OES port 330 in the vertical direction DR3. That is, the width W5 of the cap 380 in the vertical direction DR3 may be greater than the width W1 of the flange 331 in the vertical direction DR3.

As shown in FIGS. 8 and 9, the OES lens 332 may receive the first light L1 emitted from the plasma at the first position P1 at a position corresponding to the first position P1. The OES sensor 350 may measure the first plasm data by sensing the plasma state at the first position P1 using the first light L1 provided through the OES lens 332 at the position corresponding to the first position P1.

Subsequently, as shown in FIGS. 10 and 11, the OES lens 332 may move to a position corresponding to the second position P2 and receive the second light L2 emitted from the plasma at the second position P2. The OES sensor 350 may measure the second plasma data by sensing the plasma state at the second position P2 using the second light L2 provided through the OES lens 332 at the position corresponding to the second position P2.

Hereinafter, a method of manufacturing a semiconductor device according to another exemplary embodiment of the present disclosure will be described with reference to FIGS. 8 to 12. Differences from the method of manufacturing the semiconductor device shown in FIG. 3 will be mainly described.

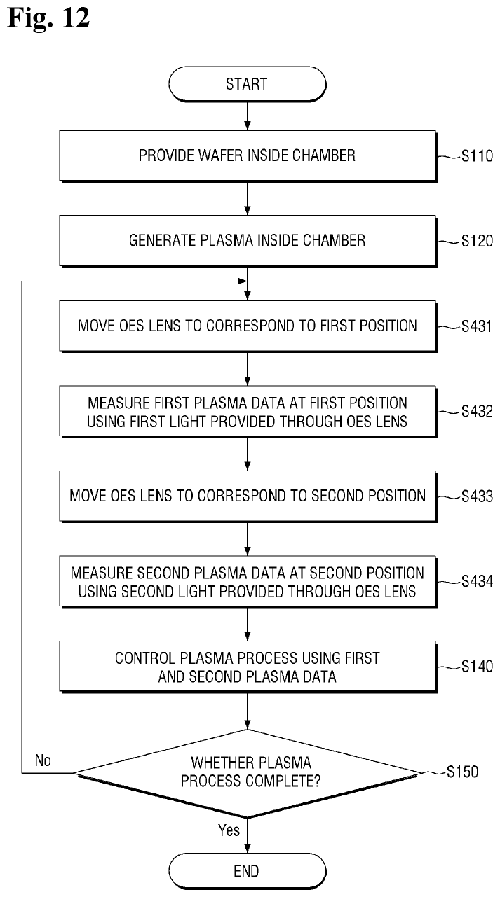

FIG. 12 is a flowchart illustrating a method of manufacturing a semiconductor device according to still another exemplary embodiment of the present disclosure.

Referring to FIGS. 8 to 12, after plasma is generated inside the chamber 100 using the process gas provided from the gas feeder 104 (S120), the OES lens 332 may be moved to correspond to the first position P1 (S431). The OES lens 332 may receive the first light L1 emitted from the plasma at the first position P1 at a position corresponding to the first position P1.

Then, the OES sensor 350 may measure the first plasma data by sensing the plasma state at the first position P1 using the first light L1 provided through the OES lens 332 at the position corresponding to the first position P1 (S432).

Subsequently, the OES lens 332 may be moved to correspond to the second position P2 (S433). The OES lens 332 may receive the second light L2 emitted from the plasma at the second position P2 at a position corresponding to the second position P2.

Then, the OES sensor 350 may measure the second plasma data by sensing the plasma state at the second position P2 using the second light L2 provided through the OES lens 332 at the position corresponding to the second position P2 (S434).

Subsequently, the control unit 370 may control the plasma process inside the chamber 100 using the first plasma data measured at the first position P1 and the second plasma data measured at the second position P2 (S140).

Next, when the plasma process inside the chamber 100 is not completed, the movement of the OES sensor 350 to a position corresponding to the first position P1, the measurement of the first plasma data using the OES sensor 350, the movement of the OES sensor 350 to a position corresponding to the second position P2, the measurement of the second plasma data using the OES sensor 350, and control of the plasma process using the control unit 370 may be repeated again (S150).

When the plasma process inside the chamber 100 is completed, the movement of the OES sensor 350 to a position corresponding to the first position P1, the measurement of the first plasma data using the OES sensor 350, the movement of the OES sensor 350 to a position corresponding to the second position P2, the measurement of the second plasma data using the OES sensor 350, and control of the plasma process using the control unit 370 may be stopped.

In the plasma processing apparatus and the method of manufacturing a semiconductor device using the plasma processing apparatus according to some embodiments of the present disclosure, by disposing the OES lens 332 to be movable in the vertical direction DR3, light generated from the plasma at various positions spaced apart from each other in the vertical direction DR3 inside the chamber 100 may be received. Due to this, the plasma processing apparatus and the method of manufacturing a semiconductor device using the plasma processing apparatus according to some embodiments of the present disclosure can effectively monitor the plasma state generated inside the chamber 100 to improve the reliability of the plasma process.

Although embodiments of the present invention have been described with reference to the above and the accompanying drawings, it could be understood that those of ordinary skill in the art to which the present invention pertains can practice the present invention in other specific forms without changing its technical spirit or essential features. Therefore, it should be understood that the embodiments described above are illustrative in all respects and not limiting.

What is claimed is:

1. An apparatus for a plasma process comprising:
a chamber, in which a plasma process is performed;
a chuck disposed inside the chamber and provided with a wafer;
a gas feeder disposed on the chuck and for providing a process gas to an inside of the chamber;
an OES port extending in a vertical direction along a sidewall of the chamber, and for receiving each of a first light emitted from plasma at a first position and a second light emitted from plasma at a second position closer to the gas feeder than the first position;
an OES sensor for sensing the first light to measure first plasma data, and sensing the second light to measure second plasma data; and
a control unit for controlling the plasma process using the first and second plasma data.

2. The apparatus of claim 1, wherein, in the OES port, a width in the vertical direction is greater than a width in a horizontal direction.

3. The apparatus of claim 1 further comprises,
an optical cable connecting the OES port and the OES sensor.

4. The apparatus of claim 1, wherein the OES port comprises a flange connected to an inner wall of the chamber and an OES lens surrounded by the flange,
wherein the OES lens comprises,
a first OES lens for receiving the first light, and
a second OES lens spaced apart from the first OES lens in the vertical direction, and for receiving the second light.

5. The apparatus of claim 4, wherein the OES sensor comprises,
a first OES sensor for sensing the first light to measure the first plasma data, and
a second OES sensor for sensing the second light to measure the second plasma data.

6. The apparatus of claim 5 further comprises,
a first optical cable connecting the first OES lens and the first OES sensor; and
a second optical cable connecting the second OES lens and the second OES sensor.

7. The apparatus of claim 1, wherein the OES port comprises a flange connected to an inner wall of the chamber and an OES lens surrounded by the flange,
wherein, in a state, in which the flange is fixed, the OES lens moves in the vertical direction to receive each of the first light and the second light.

8. The apparatus of claim 7 further comprises,
an optical cable connected to the OES lens, and moving in the vertical direction, and
a cap connected to each of the OES lens and the optical cable, and moving in the vertical direction along a sidewall of the chamber.

9. The apparatus of claim 8, wherein a width of the cap in the vertical direction is greater than a width of the OES port in the vertical direction.

10. The apparatus of claim 1, wherein the chuck comprises,
a lower electrode provided with the wafer, and
an RF rod for providing an RF signal from a lower portion of the lower electrode to the lower electrode.

11. An apparatus for a plasma process comprising:
a chamber, in which a plasma process is performed;
a flange extending in a vertical direction along a sidewall of the chamber and having a width in the vertical direction greater than a width in a horizontal direction;
an OES lens surrounded by the flange, and for receiving each of a first light emitted from plasma at a first position and a second light emitted from plasma at a second position spaced apart from the first position in the vertical direction;
an OES sensor for sensing the first light to measure first plasma data, and sensing the second light to measure second plasma data;
an optical cable connecting between the OES lens and the OES sensor; and
a control unit for controlling the plasma process using the first and second plasma data.

12. The apparatus of claim 11, wherein, in the OES lens, a width in the vertical direction is greater than a width in a horizontal direction.

13. The apparatus of claim 11, wherein the OES lens comprises,
a first OES lens for receiving the first light, and
a second OES lens spaced apart from the first OES lens in the vertical direction, and for receiving the second light.

14. The apparatus of claim 11, wherein the OES lens moves in the vertical direction to receive each of the first light and the second light.

15. A method for manufacturing a semiconductor device comprising:
providing a wafer inside a chamber, in which a plasma process is performed;
generating plasma inside the chamber;
providing each of a first light emitted from plasma at a first position and a second light emitted from plasma at a second position spaced apart from the first position in a vertical direction to an OES sensor through an OES port formed in a sidewall of the chamber;
measuring first plasma data by sensing the first light, and measuring second plasma data by sensing the second light; and
controlling the plasma process using the first and second plasma data,
wherein, in the OES port, a width in the vertical direction is greater than a width in a horizontal direction.

16. The method of claim 15, wherein measuring each of the first and second plasma data comprises,
measuring the second plasma data by sensing the second light while measuring the first plasma data by sensing the first light.

17. The method of claim 15, wherein the OES port comprises a first OES lens and a second OES lens spaced apart from the first OES lens in the vertical direction,
wherein measuring each of the first and second plasma data comprises,
providing the first light to the OES sensor through the first OES lens, and providing the second light to the OES sensor through the second OES lens.

18. The method of claim 15, wherein measuring each of the first and second plasma data comprises,
measuring the first plasma data using the first light, and
measuring the second plasma data using the second light after measuring the first plasma data.

19. The method of claim 18, wherein measuring each of the first and second plasma data comprises,
moving an OES lens formed in the OES port to correspond to the first position,
measuring the first plasma data using the first light provided through the OES lens,
moving the OES lens to correspond to the second position, and
measuring the second plasma data using the second light provided through the OES lens.

20. The method of claim 18, wherein controlling the plasma process comprises,
repeatedly performing a process cycle including measuring the first plasma data and measuring the second plasma data until the plasma process is completed.
